(19) United States
(12) Patent Application Publication
(10) Pub. No.: US 2017/0292873 A1
(43) Pub. Date: Oct. 12, 2017

(54) VIBRATION TESTING TOOL

(71) Applicant: Teradyne, Inc., North Reading, MA (US)

(72) Inventors: Robert M. Schleicher, Winchester, MA (US); John D. Moniz, Fall River, MA (US); Anthony J. Suto, Sterling, MA (US); Robert J. Muller, Westford, MA (US)

(21) Appl. No.: 15/092,780

(22) Filed: Apr. 7, 2016

(51) Int. Cl. G01H 1/00; H05K 7/14; G11B 33/02

(52) U.S. Cl. CPC G01H 1/00; G11B 33/02; H05K 7/1427

(57) ABSTRACT

An example apparatus, such as a vibration testing tool, includes: a housing configured to fit into, and to connect to, a test slot configured to house a device for testing, with the test slot being part of a device test system; accelerometers connected to the housing and configured to output signals representing movement of the apparatus; and circuitry connected to the housing to generate data based on the signals, with the data being usable to determine multiple independent accelerations of the apparatus.

### TECHNICAL FIELD

This specification relates generally to a tool for testing vibrations that occur, e.g., in slots of a hard disk drive (HDD) test system.

### BACKGROUND

Manufacturers typically test devices, such as storage devices, for compliance with various requirements. Device test systems exist for testing large numbers of devices serially or in parallel. Device test systems typically include one or more test racks having multiple test slots that receive devices for testing. Vibrations in test slots can affect the accuracy of testing performed on the devices. Tools exist for determining the amount of vibrations in a test slot. Information about these vibrations may be used to increase test accuracy.

### SUMMARY

An example apparatus, such as a vibration testing tool, comprises: a housing configured to fit into, and to connect to, a test slot configured to house a device for testing, with the test slot being part of a device test system; accelerometers connected to the housing and configured to output signals representing movement of the apparatus; and circuitry connected to the housing to generate data based on the signals, with the data being usable to determine multiple independent accelerations of the apparatus. The example apparatus may include one or more of the following features, either alone or in combination.

The apparatus may include memory connected to the housing. The circuitry may be configured to store the data in the memory. The apparatus may include a connector connected to the housing. The connector may be for mating to a complementary connector in the test slot. The connector may comprise one or more electrical conduits to pass the data to one or more electrical conduits that are part of the test rack and that are connected to the complementary connector.

The apparatus may be in communication with a computer system through the one or more electrical conduits that are part of the test rack, and not through cables external to the hard disk drive test system. The data may be usable to determine independent accelerations of the apparatus.

The circuitry may define a data acquisition system. The data acquisition system may comprise front end circuitry to remove signals having frequencies above and/or below one or more thresholds, and analog-to-digital circuitry to convert signals that remain to produce the data. The apparatus may include one or more weights connected to the housing. The one or more weights may be arranged to approximate a mass distribution of a hard disk drive to be tested by the hard disk drive test system. The apparatus may include a slot to receive a card containing the memory. The card may be movable into, or out of, the slot.

The circuitry may be part of a printed circuit board that is mounted to the housing; the accelerometers may be within the housing; and the apparatus may include conduits to transport the signals from the accelerometers to the printed circuit board. The circuitry may be controllable to store the data in the memory, to output the data to an external system, or to both store the data in memory and to output the data to an external system.

An example test system may include a computer system; test slots configured to hold devices during testing; and a rack configured to hold the test slots. The rack may comprise electrical conduits connected to, and between, the test slots and the computer system to enable communication between the test slots and the computer system. A robot may be configured to service the test slots by moving devices into, and out of, the test slots. At least one of the devices may comprise a testing tool configured to test vibration of test slots. The testing tool may comprise: a housing configured to fit into, and to connect to, a test slot; memory connected to the housing; accelerometers connected to the housing and configured to output signals representing movement of the testing tool; and circuitry connected to the housing to generate data based on the signals, and to store the data in the memory, with the data being usable to determine multiple independent accelerations of the apparatus. The example test system may include one or more of the following features, either alone or in combination.

The devices may include hard disk drives and the test system may be configured to test hard disk drives following verification based on testing vibration of the slots using the testing tool. The devices may include mobile telephone cameras and the test system may be configured to test mobile telephone cameras following verification based on testing vibration of the slots using the testing tool. The devices may comprise one or more of the following: biological samples, semiconductor devices, mechanical assemblies, or microelectromechanical systems (MEMS) devices.

The accelerometers may have a dynamic range of +/−5 g. The testing tool may comprise a connector connected to the housing. The connector may be for mating to a complementary connector in the test slot. The connector may comprise one or more electrical conduits to pass the data to one or more electrical conduits that are part of the rack and that are connected to the complementary connector.

The testing tool may be in communication with the computer system through the one or more electrical conduits that are part of the rack, and not through cables external to the hard disk drive test system. The data may be usable to determine independent accelerations of the test system.

The circuitry may define a data acquisition system. The data acquisition system may comprise front end circuitry to remove signals having frequencies above and/or below one or more thresholds, and analog-to-digital circuitry to convert signals that remain to produce the data.

The testing tool may comprise one or more weights connected to the housing. The one or more weights may be arranged to approximate a mass distribution of a hard disk drive to be tested by the hard disk drive test system. The testing tool may comprise a slot to receive a card containing the memory. The card may be movable into, or out of, the slot.

The circuitry may be part of a printed circuit board that is mounted to a bottom of the housing; the accelerometers may be within the housing; and the testing tool may comprise conduits to transport the signals from the accelerometers to the printed circuit board. The circuitry may be controllable to store the data in the memory, to output the data to the computer system, or to both store the data in memory and to output the data to the computer system.

Any two or more of the features described in this specification, including in this summary section, can be combined to form implementations not specifically described herein.

The systems and techniques described herein, or portions thereof, can be implemented as/controlled by a computer program product that includes instructions that are stored on one or more non-transitory machine-readable storage media, and that are executable on one or more processing devices to control (e.g., coordinate) the operations described herein. The systems and techniques described herein, or portions thereof, can be implemented as an apparatus, method, or electronic system that can include one or more processing devices and memory to store executable instructions to implement various operations.

The details of one or more implementations are set forth in the accompanying drawings and the description below. Other features, objects, and advantages will be apparent from the description and drawings, and from the claims.

### DESCRIPTION OF THE DRAWINGS

FIG. 1 is a perspective view of a front of an example test system that includes a rack, a mast, a shuttle and an elevator.

FIG. 2 is a perspective close-up view of the shuttle and the elevator shown in the example system of FIG. 1.

FIG. 3 is a perspective view of an example slot.

FIG. 4 is a perspective view of a test system and control center.

FIG. 5 is a perspective view of an example vibration testing tool.

FIG. 6 is a perspective, exploded view of the vibration testing tool.

FIG. 7 is a block diagram of an example data acquisition system that may be included in the vibration testing tool.

Like reference numerals in different figures indicate like elements.

### DETAILED DESCRIPTION

In a test system, devices under test (DUTs) are movable into, and out of, test slots for testing. The test slots may be mounted on racks using isolators that are configured to reduce the amount and/or frequencies of vibrations transmitted between the slots and the rack. This can be beneficial when testing devices that have moving parts, and whose movement can result in vibrations that can be transmitted to the rack and thus to other slots in the rack and/or parts that are sensitive to externally-induced vibration. For example, a hard disk drive (HDD) includes a spinning magnetic disk. Movement of the spinning magnetic disk causes vibrations that can be transmitted to the slot which, in turn, can be transmitted to the rack and to other slots. Vibrations, such as these, can adversely affect testing performed in other slots.

Described herein is an example of a tool for determining vibrations in a test slot of a test system. The vibration testing tool (or simply “tool”) is configured to have about the same size and mass distribution as a DUT to be tested in the test system. In this example, the device to be tested is a hard disk drive (HDD); however, other types of devices may be tested, as described herein. Consequently, in this case, the vibration testing tool is about the same size as, and has about the same mass distribution as, a HDD. The vibration testing tool is movable into, and out of, a test slot. Inside the test slot, the vibration testing tool connects, both electrically and mechanically, to the same interface in the test slot to which the HDD would connect, thereby enabling communication with the vibration testing tool to occur to, and through, the test system. Furthermore, the vibration testing tool is clamped to the test slot, so that movement of the test slot is transferred to the vibration testing tool. While in the test slot, the vibration testing tool stores data representing vibrations, including shock, that would occur in the test slot during testing using the test system. The vibration testing tool either stores the data locally (e.g., in a removable memory card in the vibration testing tool), or outputs the data to an external system, such as a test computer system that is part of the test system. Because the vibration testing tool is connected to the test system in the same way as a HDD would be connected, the vibration testing tool can output the data through electrical conduits that are already part of the test system.

In an example implementation, the vibration testing tool includes a housing configured to fit into, and to connect to, a test slot that is used to hold a DUT for testing. A memory, such as a removable memory card, is connected to the housing. Accelerometers are also connected to (e.g., inside) the housing and are configured to output signals representing movement of the vibration testing tool while in the housing. The movement of the vibration testing tool in the housing includes vibrations, including shock, experienced by the vibration testing tool in the housing during operation of the test system. Since the vibration testing tool is clamped within the test slot, the movement of the vibration testing tool reflects movement (e.g., vibrations) of the test slot. Circuitry, which is also connected to the housing, generates data based on the signals from the accelerometers, stores that data in the memory, and, in some cases, outputs that data to a test computer system through existing conduits in the test system. The data represents multiple (e.g., six) independent accelerations of the vibration testing tool, and thus the test slot, and is usable to determine vibrations, including shock, that the test slot experienced. Because the vibration testing tool stores the data locally or transmits the data through existing electrical conduits in the test system, the vibration testing tool need not include additional wiring to/from the vibration testing tool for data transmission. This is advantageous because such additional wiring can adversely affect vibration data.

More specifically, additional wiring between a vibration testing tool and an external system can introduce vibrations into the test system, and thus the test slots. As a result, it can be difficult to detect which vibrations are a result of operations in the test slot, and which vibrations are a result of the wires contacting, or otherwise affecting, the test system. By reducing the need for such wires, the vibration testing tool described herein can provide vibration data having increased accuracy. Furthermore, the elimination of such wires, and the construction of the vibration testing tool to resemble a device under test (e.g., an HDD), enables the vibration testing tool to be moved into, and out of, test slots using automation, such as robotics. As a result, vibration testing throughput can be increased relative to systems that require manual insertion and removal of a vibration testing tool.

In prior practice, vibration testing was performed prior to shipment of a test system, and also at the actual test location. For example, prior to shipment, the entire contingent of test slots was tested for vibration. At the actual test location, only a subset of the test slots were tested for vibration. However, since the vibration testing tool described herein enables automation of vibration testing using, e.g., robotics that are already part of the test system, vibration testing of all test slots may be performed prior to shipment and also at the actual test location. Testing, however, may also be performed as in prior practice, or using any other appropriate protocols.

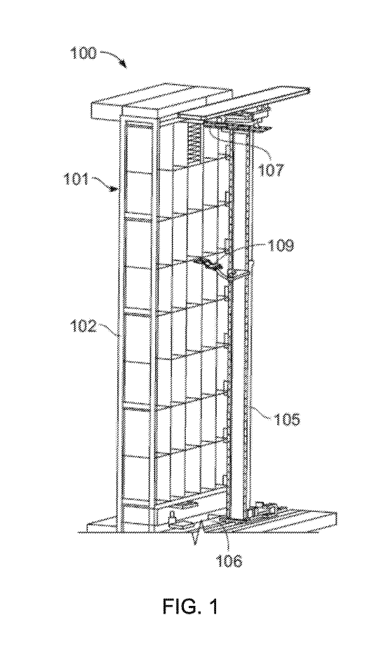

An example of a test system with which the vibration testing tool may be used is described with respect to FIGS. 1A, 1B through FIG. 15 of U.S. patent application Ser. No. 13/834,803 (Publication No. 2014/0271064). The contents of U.S. patent application Ser. No. 13/834,803 are incorporated herein by reference. However, the vibration testing tool is not limited to use with the device test system described therein, and may be usable with any appropriate test system.

Described in U.S. patent application Ser. No. 13/834,803 is a system in which racks of slots are serviced by a robotic mast. A shuttle moves devices to be tested (e.g., hard drives) along a track from a feeder to a mast arm, and devices that have been tested from the mast arm to the feeder. The feeder may service the test slots in parallel with the shuttle moving the devices (tested or untested) between the feeder and the mast. The vibration testing tool described herein may be moved by the system in place of a device to be tested, and moved into a test slot for vibration testing.

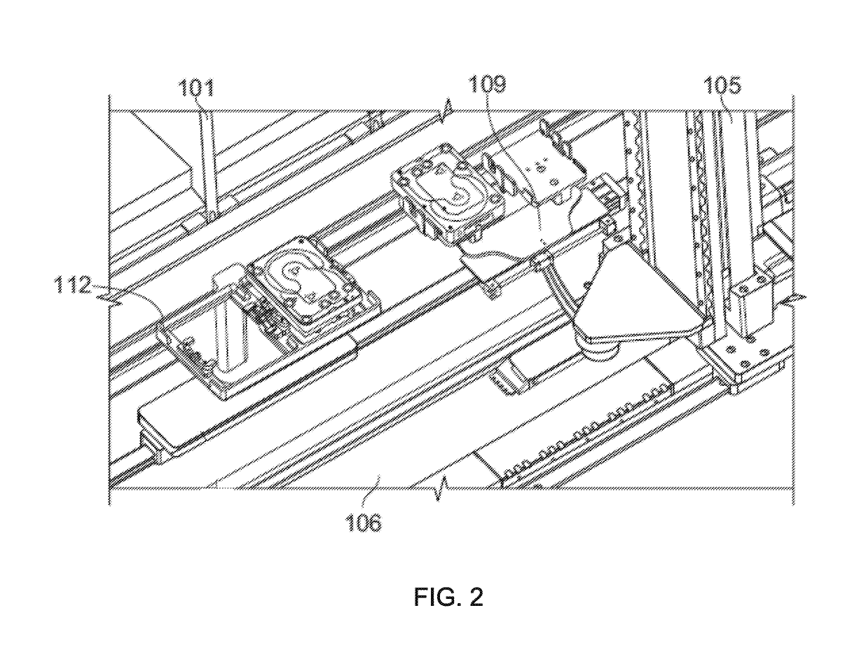

FIGS. 1 and 2 show part of an example storage device test system 100 of the type described in U.S. patent application Ser. No. 13/834,803, which may include multiple test racks 101 (only one is depicted) and automated robotic elements to move storage devices or the vibration testing tool between a feeder and the test racks. The test racks are arranged in horizontal rows and vertical columns, and mounted in one or more chassis. As shown in FIG. 1, each test rack 101 generally includes a chassis 102. Chassis 102 can be constructed from a plurality of structural members (e.g., formed sheet metal, extruded aluminum, steel tubing, and/or composite members) that are fastened together and that together define receptacles for corresponding test slots or packs of test slots. Each rack houses multiple test slots. Different ones of the test slots may be used for performing the same or different types of tests and/or for testing the same or different types of storage devices.

In an example implementation, a rack 101 is served by a robotic mast. In this example, “servicing” includes moving untested storage devices into test slots in the rack, and moving tested storage devices out of test slots in the rack. “Servicing” also includes moving the vibration testing tool into, and out of, a test slot, and between test slots. An example of a mast 105 used to service test rack 101 is shown in FIG. 1.

In some implementations, track 106 may run substantially parallel to the front (see, e.g., FIGS. 1 and 2) of rack 101. In this context, the “front” of a rack is the side of the rack from which storage devices can be loaded into, and removed from, slots in the rack. In other implementations, storage devices or the vibration testing tool can be loaded into, and removed from, both sides (back and front) of a rack. In such implementations, there may be a track on each side (e.g., front and back) of the rack, with each such track serviced by a separate mast.

In some implementations, mast 105 includes an automation arm 107 for removing storage device or the vibration testing tool from, and inserting storage devices or the vibration testing tool into, corresponding test slots in the rack. In an example implementation, automation arm 107 is a structure that supports a storage device or the vibration testing tool, and that projects from the mast to a slot during docking (engaging) with a slot, and that retracts towards the mast when disengaging from the slot. Automation arm 107 is movable vertically along mast 105 to align to a slot to be serviced. In this regard, as noted above, mast 105 moves horizontally along track 106. The combination of the mast's horizontal motion and the automation arm's vertical motion enables servicing of any slot in a test rack. At least part of the horizontal and vertical motions may be concurrent.

The automation arm is configured to interact with a corresponding slot during loading of an untested device and unloading of a tested device. As explained in more detail below, when docked, a device in a slot (either a tested device or the vibration testing tool) may be moved, from the slot, to automation arm 107, to an elevator 109. In some implementations, the elevator may be considered part of the mast. A device may be moved from elevator 109, to automation arm 107, to the slot. In some implementations, the automation arm remains in contact with the slot for a whole time during transfer of a device out of a slot, and of a device into that same slot. This, however, need not be the case in all system implementations.

The test system may transport vibration testing tools among a feeder, a shuttle 112, elevator 109, automation arm 107, and test slots 101 in the same manner as the test system transports tested and untested storage devices. However, when transporting the vibration testing tool, the test system may be programmed to transport the same vibration testing tool between test slots. That is, when transporting tested and untested storage devices, the test system is typically programmed to transport untested storage devices from the feeder, to a test slot, and to transport tested storage devices from a test slot to the feeder. When transporting the vibration testing tool, the test system may be programmed to transport a vibration testing tool from one test slot, where vibration testing is performed on that test slot; to another test slot, where vibration testing is performed on that other test slot; to still another test slot, where vibration testing is performed on that still other test slot; and so forth, without returning the vibration testing tool to the feeder. In the meantime, the system may introduce additional vibration testing tools into the test rack, and move them from test slot to test slot in the same manner to perform vibration testing on the test slots. Movement may be programmed, and coordinated, to coincide with completion of vibration testing in individual test slots. Vibration testing may be asynchronous, e.g., not performed at the same time, enabling the test system to perform different operations at different times.

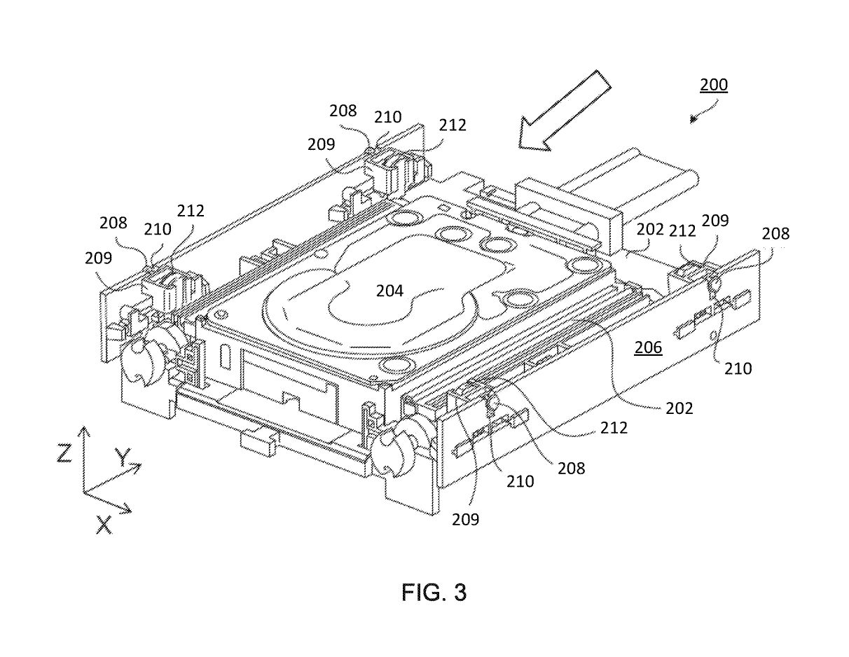

FIG. 3 shows an example of a test slot 200 that may be used in a test system of the type described herein. Slot 200 includes, among other things, a tray 202. Tray 202 holds a device 204, such as an HDD or the vibration testing tool. The test slot includes structure to mount slot 200 to rack 206. In some implementations, slot 200 is mounted to rack 206 using isolators, such as grommets 208. Grommets 208 are rubber in some implementations; however, grommets 208 may include any appropriate vibration-reducing (e.g., elastic) material. In some implementations, each grommet 208 is fixed to a corresponding arm 209 of the slot frame. Grommets 208 fit into corresponding grooves 210 in rack 206. Grommets 208 are movable within those grooves and, furthermore, are flexible. As such, grommets 208 aid in reducing transmission of vibrations from the slot to the rack. That is, at least some vibrations may be absorbed through movement of the grommets in the slots and by the relative softness or pliability of the grommets. Slot 200 may include an electrical and mechanical connector (not shown), which connects to electrical conduits running through the test rack. A device in the slot, such as the vibration testing tool, connects electrically and mechanically to this connector. The resulting connection enables communication between a test computer system and a device, such as the vibration testing tool, in the slot.

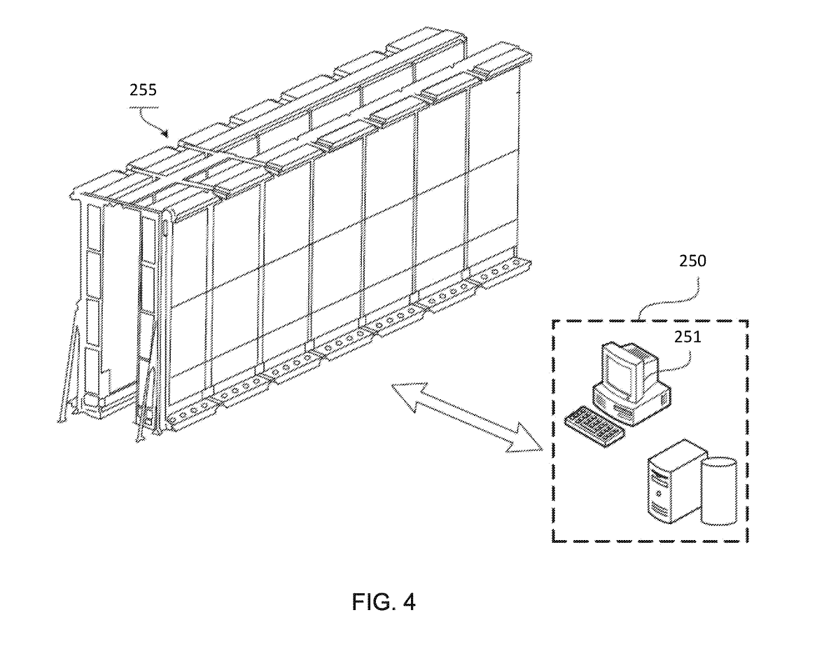

Referring to FIG. 4, the test system may include a control center 251 housing a computing device 251. Computing device 251 may include one or more digital computers, examples of which include, but are not limited to, laptops, desktops, workstations, personal digital assistants, servers, blade servers, mainframes, and other appropriate computing devices. Computing device 251 may also include various forms of mobile devices, examples of which include, but are not limited to, personal digital assistants, cellular telephones, smartphones, and other similar computing devices. The components described herein, their connections and relationships, and their functions, are meant to be examples only, and are not meant to limit implementations of the technology described and/or claimed herein.

Computing device 251 includes appropriate features that enable computing device 251 to communicate through electrical conduits in the test rack, or wirelessly, with processing devices in the test slots. Computing device 251 (or other devices directed by computing device 251) also controls various other features of the example test system described herein, such as the feeder(s), the mast(s), the shuttle(s), and so forth.

As noted, test system 255 may implement wired or wireless communications between computing device 251 and processing devices in the slots, and wired or wireless communications to other features of the system (e.g., the feeder(s), the mast(s), the shuttle(s), and so forth. In some implementations, communications to/from the slots may be a combination of wired and wireless communications.

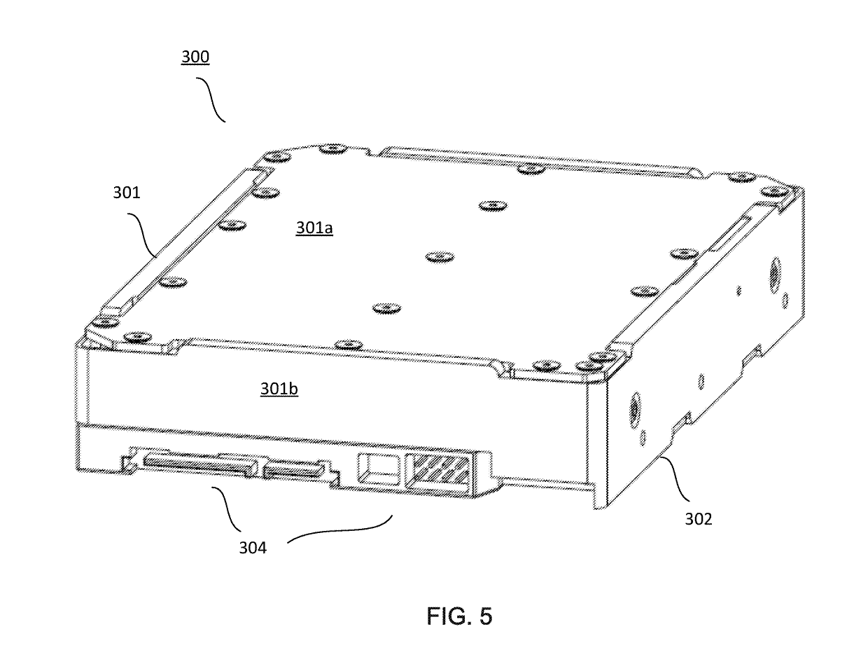

FIG. 5 shows an example vibration testing tool 300 of the type described herein. In this example, the vibration testing tool includes a metal housing 301, or case, that includes multiple (e.g., six) accelerometers (not shown in FIG. 5). The housing may include a lid 301a and a body 301b, in some examples. The accelerometers are positioned and oriented in a pattern that enables determination of six independent movements (or accelerations) of the vibration testing tool in six different directions. As described above, since the vibration testing tool is clamped within a test slot, the six independent movements of the vibration testing tool also represent six independent movements of the test slot.

In this example, the housing includes a circuit board (not shown in FIG. 5) bolted to its bottom 302. The circuit board has an interface connector mounted to it, such as (but not limited to) a 3.5 inch hard drive SATA connector, it so that its position and orientation in the test slot is the same as that of an actual HDD. This configuration allows the vibration testing tool to interface to the test system of FIGS. 1 to 4 in the same manner as would an HDD. The circuit board contains a data acquisition system that is used to collect vibration data based on signals output by the accelerometers. The data may be stored locally, e.g., on a removable micro SD drive, or read from the circuit board itself through the test system (e.g., by the test computer system).

Housing 301 is configured to have about the same size and mass distribution as a standard HDD and is, therefore, configured to fit into, and to connect to, a test slot in a test system, such as that shown in FIGS. 1 to 4. Connectors 304 are part of/connected to housing 301. A connector 304 mates to a complementary connector in a test slot, and includes one or more electrical conduits to pass data to one or more electrical conduits that are part of the test rack and that are connected to the complementary connector. For example, the electrical conduits may run through the test rack, and to the test computer system. Through these electrical conduits, communications and data may be exchanged between the vibration testing tool and the test computer system (e.g., computing device 251). As a result, in this example at least, there is no need to route communications through cables that are external to (e.g., not part of) the test system. Such external cables are therefore not used with the vibration testing tool, or incorporated into the test system. Because these cables are not used, the vibration testing tool may provide vibration test information that is more accurate than systems that employ external cables.

Memory (not shown) is also connected to housing 301. In some implementations, this memory is implemented as one or more removable memory cards that can be inserted into, and removed from, a slot in the housing; however, that is not a requirement. The memory stores vibration data generated by the vibration testing tool for one or more test slots. For example, each test slot that the vibration testing tool has tested may be identified in memory, and have its vibration data stored in association therewith. The memory may be removable so that vibration data is available and accessible even in cases where the test computer is not operational or not in communication with the test slots. In this regard, as noted above, the vibration testing tool may transmit vibration data to the test computer system through electrical conduits in the test rack, or even wirelessly as described herein. However, the test computer system may not always be operational. In such cases, the removable memory enables access to vibration test data without requiring an operational test computer.

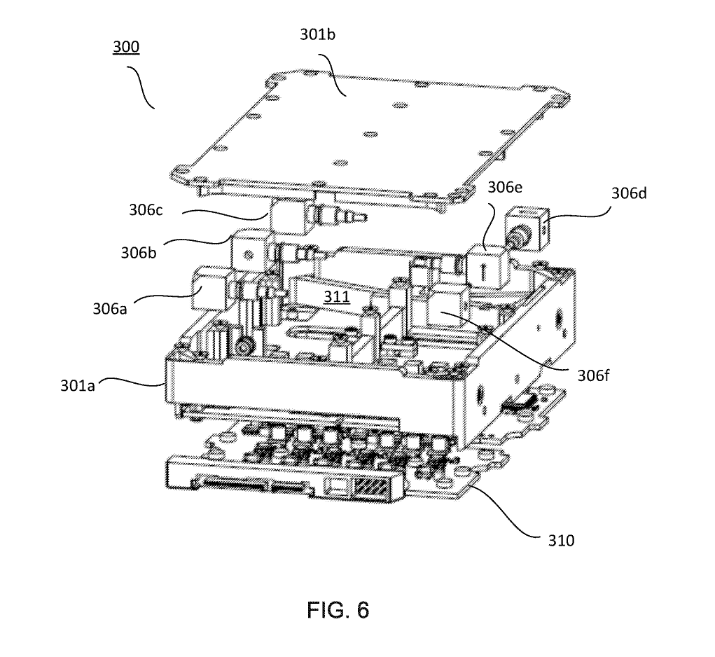

Referring also to FIG. 6, vibration testing tool 300 also includes multiple accelerometers 306a to 306f. These accelerometers are connected to (in this case, are inside) the housing and are configured to output analog signals representing movement of the vibration testing tool, and thus movement of the test slot in which the vibration testing tool is clamped. In this example, there are six accelerometers that are positioned and oriented in a pattern to enable determination, based on their output signals, of six independent accelerations of the vibration testing tool in six principle directions. In some examples, these directions include the six degrees of freedom, namely X, Y and Z Cartesian directions, and pitch, yaw, and roll. However, the vibration testing tool is not limited to use of six accelerometers, or to outputting data to determine accelerations in these directions. In some implementations, the accelerometers have a dynamic range of +/−5 g; however, accelerometers having different operational ranges than this may be used.

The vibration testing tool also includes a data acquisition system. As indicated above, the data acquisition system may be implemented on a circuit board 310 (FIG. 6) connected to the bottom of the housing; however, this is not a requirement. The data acquisition system may include circuitry to generate digital data based on analog signals output from the accelerometers representing tool motion, and to store the resulting digital data in memory or to transmit the data to a remote computer system. As noted, the data is usable, e.g., by the test computer system or other appropriate processing device(s), in processes for determining multiple independent accelerations of the vibration testing tool and, thus, vibrations, including shock, experienced by the test slot during operation of the test system.

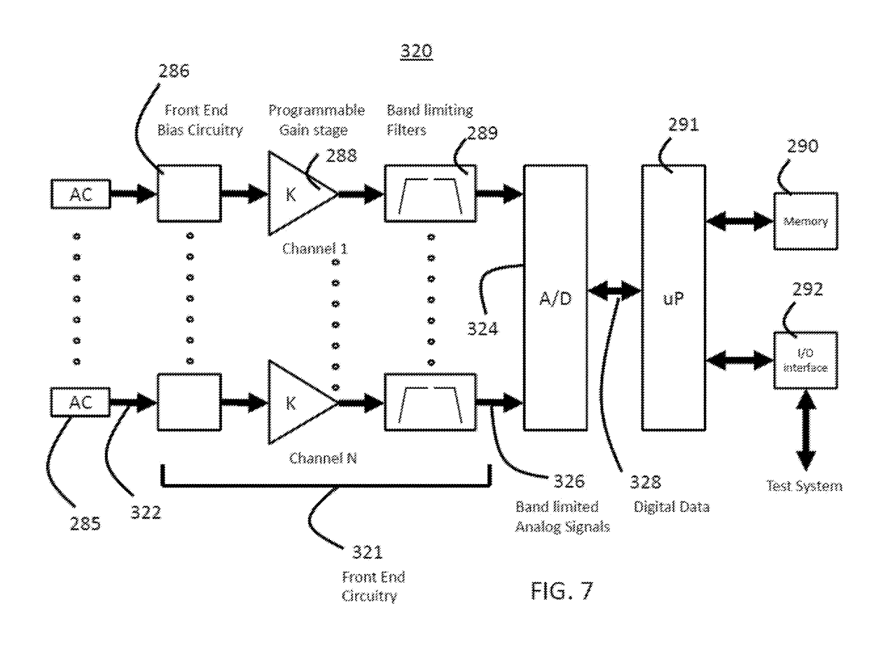

Referring to FIG. 7, in an example implementation, the data acquisition system 320 includes front end circuitry 321 to remove, from analog accelerometer signals 322 received from accelerometers (AC) 285 (e.g., accelerometers 306a to 306f), signals that having frequencies above a threshold in this example (below a threshold in other examples, or both above and below thresholds in other examples). The front end circuitry 321 may include, for each channel of data 1 to N (N>1), one or more band-limiting filters, such as low-pass filter(s) or high-pass filter(s), to band-limit the frequencies. The front end circuitry 321 may also include, for each channel, front end bias circuitry 286 and a programmable gain stage 288 to receive the accelerometer signals and to amplify the signals, if needed. Analog-to-digital circuitry 324 may include one or more analog-to-digital converters (ADCs). Analog-to-digital (ND) circuitry 324 converts the remaining (band-limited) signals 326 to digital data 328 representing the remaining signals. This digital data is sent to a microprocessor (uP) 291, which may store the data in local memory 290 (e.g., an SD card) or send the data to a test computer system (e.g., computing device 251) via input/output (I/O) interface 292.

As indicated herein, the vibration testing tool is configured to have a size and mass distribution that approximates those of a device (e.g., an HDD) to be tested in a test slot. Accordingly, the vibration testing tool may include one or more weights, such as weight 311 (FIG. 6), which are strategically placed either inside or outside of housing 301, and that approximate the mass distribution of a device to be tested.

The vibration testing tool described herein may be used to detect vibrations in any appropriate range. For example, the vibration testing tool may be used to detect vibrations between 0 milli-g's and 30 milli-g's.

The example vibration testing tool and systems described herein focus on HDDs, e.g., generally. a non-volatile storage device that stores digitally encoded data on rapidly rotating platters with magnetic surfaces. However, the example vibration testing tool and systems described herein are usable with any type of storage or non-storage device that requires vibration testing. Such devices may include, but are not limited to, biological samples, semiconductor devices, mechanical assemblies, microelectromechanical systems (MEMS) devices, and so forth.

In an example, the vibration testing tool may be configured to have a size and mass distribution that are similar to those of a mobile telephone containing a camera. A version of the test system described herein may be configured to test mobile telephone cameras in slots. Consequently, a vibration testing tool configured to resemble a mobile telephone having a camera may be moved into, and out of, slots by the robotics described herein in order to test vibrations of those slots, as described herein.

Testing performed by the example test system described herein, which includes vibration testing and controlling (e.g., coordinating movement of) various automated elements to operate in the manner described herein or otherwise, may be implemented using hardware or a combination of hardware and software. For example, a test system like the ones described herein may include various controllers and/or processing devices located at various points in the system to control operation of the automated elements. A central computer (e.g., computing device 251) may coordinate operation among the various controllers or processing devices. The central computer, controllers, and processing devices may execute various software routines to effect control and coordination of the various automated elements.

In this regard, vibration testing using the vibration testing tool described herein may be controlled by a computer, e.g., by sending signals to and from one or more wired and/or wireless connections to each test slot. The testing can be controlled, at least in part, using one or more computer program products, e.g., one or more computer program tangibly embodied in one or more information carriers, such as one or more non-transitory machine-readable media, for execution by, or to control the operation of, one or more data processing apparatus, e.g., a programmable processor, a computer, multiple computers, and/or programmable logic components.

A computer program can be written in any form of programming language, including compiled or interpreted languages, and it can be deployed in any form, including as a stand-alone program or as a module, component, subroutine, or other unit suitable for use in a computing environment. A computer program can be deployed to be executed on one computer or on multiple computers at one site or distributed across multiple sites and interconnected by a network.

Actions associated with implementing all or part of the testing can be performed by one or more programmable processors executing one or more computer programs to perform the functions described herein. All or part of the testing can be implemented using special purpose logic circuitry, e.g., an FPGA (field programmable gate array) and/or an ASIC (application-specific integrated circuit).

Processors suitable for the execution of a computer program include, by way of example, both general and special purpose microprocessors, and any one or more processors of any kind of digital computer. Generally, a processor will receive instructions and data from a read-only storage area or a random access storage area or both. Elements of a computer (including a server) include one or more processors for executing instructions and one or more storage area devices for storing instructions and data. Generally, a computer will also include, or be operatively coupled to receive data from, or transfer data to, or both, one or more machine-readable storage media, such as mass storage devices for storing data, e.g., magnetic, magneto-optical disks, or optical disks. Machine-readable storage media suitable for embodying computer program instructions and data include all forms of non-volatile storage area, including by way of example, semiconductor storage area devices, e.g., EPROM, EEPROM, and flash storage area devices; magnetic disks, e.g., internal hard disks or removable disks; magneto-optical disks; and CD-ROM and DVD-ROM disks.

Any “electrical connection” as used herein may imply a direct physical connection or a wired or wireless connection that includes intervening components but that nevertheless allows electrical signals to flow between connected components. Any “connection” involving electrical circuitry mentioned herein, unless stated otherwise, is an electrical connection and not necessarily a direct physical connection regardless of whether the word “electrical” is used to modify “connection”.

Elements of different implementations described herein may be combined to form other embodiments not specifically set forth above. Elements may be left out of the structures described herein without adversely affecting their operation. Furthermore, various separate elements may be combined into one or more individual elements to perform the functions described herein.

Features of the test system described herein may be combined with features of the test system described in U.S. patent application Ser. No. 13/834,803. U.S. patent application Ser. No. 13/834,803 is incorporated herein by reference.

What is claimed is:

1. An apparatus comprising:
a housing configured to fit into, and to connect to, a test slot configured to house a device for testing, the test slot being part of a device test system;
accelerometers connected to the housing and configured to output signals representing movement of the apparatus; and
circuitry connected to the housing to generate data based on the signals, the data being usable to determine multiple independent accelerations of the apparatus.

2. The apparatus of claim 1, further comprising:
memory connected to the housing;
wherein the circuitry is configured to store the data in the memory.

3. The apparatus of claim 1, further comprising:
a connector connected to the housing, the connector for mating to a complementary connector in the test slot, the connector comprising one or more electrical conduits to pass the data to one or more electrical conduits that are part of the test rack and that are connected to the complementary connector.

4. The apparatus of claim 1, wherein the apparatus is in communication with a computer system through the one or more electrical conduits that are part of the test rack, and not through cables external to the hard disk drive test system.

5. The apparatus of claim 1, wherein the data is usable to determine independent accelerations of the apparatus.

6. The apparatus of claim 1, wherein the circuitry defines a data acquisition system, the data acquisition system comprising front end circuitry to remove signals having frequencies above and/or below one or more thresholds, and analog-to-digital circuitry to convert signals that remain to produce the data.

7. The apparatus of claim 1, further comprising one or more weights connected to the housing, the one or more weights being arranged to approximate a mass distribution of a hard disk drive to be tested by the hard disk drive test system.

8. The apparatus of claim 2, further comprising:
a slot to receive a card containing the memory, the card being movable into, or out of, the slot.

9. The apparatus of claim 1, wherein the circuitry is part of a printed circuit board that is mounted to the housing;
wherein the accelerometers are within the housing; and
wherein the apparatus further comprises conduits to transport the signals from the accelerometers to the printed circuit board.

10. The apparatus of claim 1, wherein the circuitry is controllable to store the data in the memory, to output the data to an external system, or to both store the data in memory and to output the data to an external system.

11. A test system comprising:
a computer system;
test slots configured to hold devices during testing;
a rack configured to hold the test slots, the rack comprising electrical conduits connected to, and between, the test slots and the computer system to enable communication between the test slots and the computer system; and
a robot configured to service the test slots by moving devices into, and out of, the test slots;
wherein at least one of the devices comprises a testing tool configured to test vibration of test slots, the testing tool comprising:
a housing configured to fit into, and to connect to, a test slot;
memory connected to the housing;
accelerometers connected to the housing and configured to output signals representing movement of the testing tool; and
circuitry connected to the housing to generate data based on the signals, and to store the data in the memory, the data being usable to determine multiple independent accelerations of the apparatus.

12. The test system of claim 11, wherein the devices comprise hard disk drives and the test system is configured to test hard disk drives following verification based on testing vibration of the slots using the testing tool.

13. The test system of claim 11, wherein the devices comprise mobile telephone cameras and the test system is configured to test mobile telephone cameras following verification based on testing vibration of the slots using the testing tool.

14. The test system of claim 11, wherein the accelerometers have a dynamic range of +/−5 g.

15. The test system of claim 11, wherein the testing tool comprises:
a connector connected to the housing, the connector for mating to a complementary connector in the test slot, the connector comprising one or more electrical conduits to pass the data to one or more electrical conduits that are part of the rack and that are connected to the complementary connector.

16. The test system of claim 11, wherein the testing tool is in communication with the computer system through the one or more electrical conduits that are part of the rack, and not through cables external to the hard disk drive test system.

17. The test system of claim 11, wherein the data is usable to determine independent accelerations of the test system.

18. The test system of claim 11, wherein the circuitry defines a data acquisition system, the data acquisition system comprising front end circuitry to remove signals having frequencies above and/or below one or more thresholds, and analog-to-digital circuitry to convert signals that remain to produce the data.

19. The test system of claim 11, wherein the testing tool comprises one or more weights connected to the housing, the one or more weights being arranged to approximate a mass distribution of a hard disk drive to be tested by the hard disk drive test system.

20. The test system of claim 11, wherein the testing tool comprises:
a slot to receive a card containing the memory, the card being movable into, or out of, the slot.

21. The test system of claim 11, wherein the circuitry is part of a printed circuit board that is mounted to a bottom of the housing;
wherein the accelerometers are within the housing; and
wherein the testing tool comprises conduits to transport the signals from the accelerometers to the printed circuit board.

22. The test system of claim 11, wherein the circuitry is controllable to store the data in the memory, to output the data to the computer system, or to both store the data in memory and to output the data to the computer system.

23. The test system of claim 11, wherein the devices comprise one or more of the following: biological samples, semiconductor devices, mechanical assemblies, or microelectromechanical systems (MEMS) devices.
